(19) United States
(12) Patent Application Publication
(10) Pub. No.: US 2018/0323042 A1
(43) Pub. Date: Nov. 8, 2018

(54) METHOD TO MODULATE THE WAFER EDGE SHEATH IN A PLASMA PROCESSING CHAMBER

(71) Applicant: Applied Materials, Inc., Santa Clara, CA (US)

(72) Inventors: Haitao WANG, Fremont, CA (US); Anwar HUSAIN, Pleasanton, CA (US); Kartik RAMASWAMY, San Jose, CA (US); Jason A. KENNEY, Campbell, CA (US); Jeffrey LUDWIG, San Jose, CA (US); Chunlei ZHANG, Santa Clara, CA (US); Wonseok LEE, Pleasanton, CA (US)

(21) Appl. No.: 15/957,054

(22) Filed: Apr. 19, 2018

Related U.S. Application Data
(60) Provisional application No. 62/500,120, filed on May 2, 2017.

(51) Int. Cl. H01J 37/32; H01L 21/67; H01L 21/683

(52) U.S. Cl. CPC H01J 37/32642; H01L 21/67069; H01J 37/32715; H01J 2237/334; H01L 21/6833

(57) ABSTRACT

The present disclosure generally relates to methods of and apparatuses for controlling a plasma sheath near a substrate edge. The apparatus includes an auxiliary electrode that may be positioned adjacent an electrostatic chuck. The auxiliary electrode is recursively fed from a power source using equal length and equal impedance feeds. The auxiliary electrode is vertically actuatable, and is tunable with respect to ground or other frequencies responsible for plasma generation. Methods of using the same are also provided.

### CROSS-REFERENCE TO RELATED APPLICATIONS

This application claims benefit of U.S. Provisional Patent Application Ser. No. 62/500,120, filed May 2, 2017, which is herein incorporated by reference.

### BACKGROUND

### Field

Aspects of the present disclosure generally relate to methods of and apparatuses for controlling a plasma sheath near a substrate edge.

### Description of the Related Art

In the current semiconductor manufacturing industry, feature size continues to decrease and transistor structures become increasingly complicated. To meet processing demands, advanced processing control techniques are useful to control cost and maximize substrate and die yield. Normally, the dies at the edge of the substrate suffer yield issues such as contact via misalignment, and poor selectivity to a hard mask. One of the causes of these issues is the bending of a plasma sheath near the substrate edge.

Therefore, there is a need for methods and apparatus to allow fine, localized process tuning at the edge of the substrate.

### SUMMARY

In one aspect, a processing chamber comprises a chamber body; a substrate support disposed within the chamber body; a recursive distribution assembly disposed within the substrate support; an edge ring assembly disposed within the substrate support and coupled to the recursive distribution assembly, the edge ring assembly including an electrically conductive electrode; an insulating support positioned on the substrate support above the electrode; and a first silicon ring disposed on the insulating support.

In another aspect, a processing chamber comprises a chamber body; a substrate support disposed within the chamber body; a recursive distribution assembly disposed within the substrate support; an edge ring assembly disposed within the substrate support and coupled to the recursive distribution assembly, the edge ring assembly including an electrically conductive circular electrode; an insulating support positioned on the substrate support above the electrode; and a first silicon ring disposed on the insulating support.

In another aspect, a recursive distribution assembly comprises a first semi-circular element; a coaxial structure coupled to the first semi-circular element at a central portion thereof; a first vertical coupling disposed at a first end of first semi-circular element and extending orthogonally from a plane of the first semi-circular element; a second vertical coupling disposed at a second end of first semi-circular element and extending orthogonally from the plane of the first semi-circular element; a second semi-circular element connected to the first vertical coupling, the first vertical coupling connected to a central portion of the second semi-circular element; and a third semi-circular element connected to the second vertical coupling, the second vertical coupling connected to a central portion of the third semi-circular element.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of scope, as the disclosure may admit to other equally effective aspects.

FIG. 1 illustrates a cross sectional view of a processing chamber, according to one aspect of the disclosure.

FIGS. 2A-2B are schematic sectional views of a support assembly, according to one aspect of the disclosure.

FIGS. 3A-3F are schematic perspective views of a power distribution assembly, according to aspects of the disclosure.

FIGS. 4A-4C are schematic views of circuit configurations, according to aspects of the present disclosure.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

The present disclosure generally relates to methods of and apparatuses for controlling a plasma sheath near a substrate edge. The apparatus includes an auxiliary electrode that may be positioned adjacent an electrostatic chuck. The auxiliary electrode is recursively fed from a power source using equal length and equal impedance feeds. The auxiliary electrode is vertically actuatable, and is tunable with respect to ground or other frequencies responsible for plasma generation. Methods of using the same are also provided.

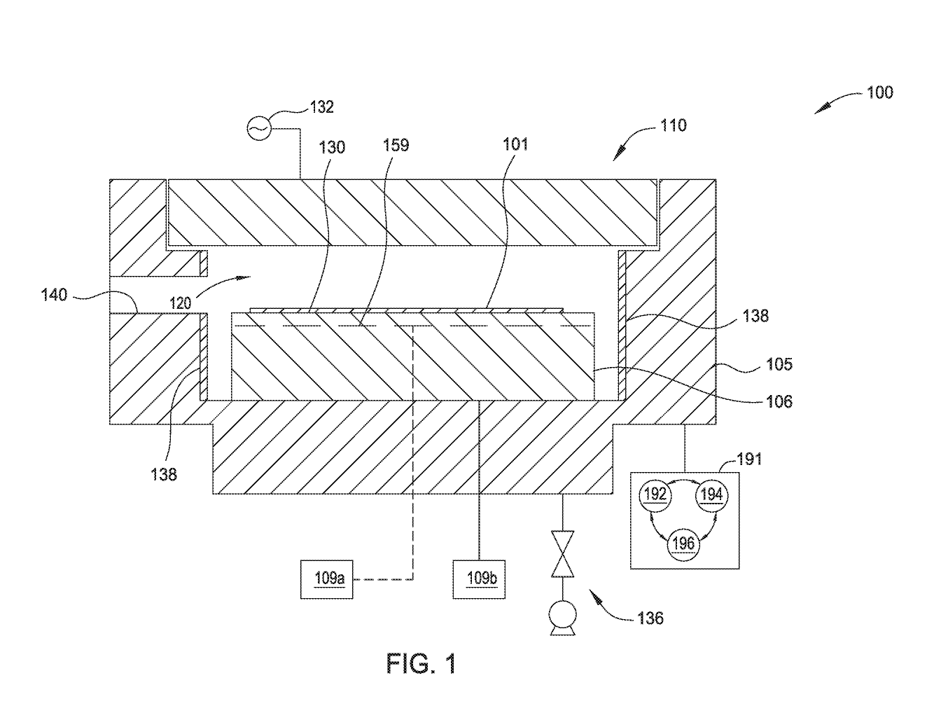

FIG. 1 is a cross sectional view of a processing chamber 100, according to one aspect of the disclosure. As shown, the processing chamber 100 is an etch chamber suitable for etching a substrate, such as substrate 101. Examples of processing chambers which benefit from aspects described herein are available from Applied Materials, Inc., located in Santa Clara, Calif. It is contemplated that other processing chambers, including those from other manufacturers, may be adapted to benefit from aspects of the disclosure.

In one embodiment, the processing chamber 100 includes a chamber body 105, a gas distribution plate assembly 110, and a support assembly 106. The chamber body 105 of the processing chamber 100 may be formed from one or more process-compatible materials, such as aluminum, anodized aluminum, nickel plated aluminum, nickel plated aluminum 6061-T6, stainless steel, as well as combinations and alloys thereof, for example. The support assembly 106 may function as an electrode in conjunction with the gas distribution plate assembly 110 such that a plasma may be formed in a processing volume 120 defined between the gas distribution plate assembly 110 and an upper surface of the support assembly 106. The support assembly 106 may be made of conductive material, such as aluminum, or a ceramic material, or a combination of both. The chamber body 105 may also be coupled to a vacuum system 136 that includes a pump and a valve. A liner 138 may also be disposed on surfaces of the chamber body 105 in the processing volume 120.

The chamber body 105 includes a port 140 formed in a sidewall thereof. The port 140 is selectively opened and closed to allow access to the interior of the chamber body 105 by a substrate handling robot (not shown). A substrate 101 can be transferred in and out of the processing chamber 100 through the port 140 to an adjacent transfer chamber and/or load-lock chamber, or another chamber within a cluster tool. The substrate 101 is disposed on the upper surface 130 of the support assembly 106 for processing. Lift pins (not shown) may be used to space the substrate 101 away from the upper surface of the support assembly 106 to enable exchange with the substrate handling robot during substrate transfer.

The gas distribution plate assembly 110 is disposed on the chamber body 105. A radio frequency (RF) power source 132 may be coupled to distribution plate assembly 110 to electrically bias the gas distribution plate assembly 110 relative to the support assembly 106 to facilitate plasma generation within the processing chamber 100. The support assembly 106 includes an electrostatic chuck 159, which may be connected to a power source 109a to facilitate chucking of the substrate 101 and/or to influence a plasma located within the processing region 120. The power source 109a includes a power supply, such as a DC or RF power supply, and is connected to one or more electrodes of the electrostatic chuck 159. A bias source 109b may optionally be coupled with the support assembly 106 to assist with plasma generation and/or control.

The bias source 109b may illustratively be a source of up to about 1000 W (but not limited to about 1000 W) of RF energy at a frequency of, for example, approximately 13.56 MHz, although other frequencies and powers may be provided as desired for particular applications. The bias source 109b is capable of producing either or both of continuous or pulsed power. In some aspects, the bias source may be capable of providing multiple frequencies, such as 13.56 MHz and 2 MHz.

The processing chamber 100 may also include a controller 191. The controller 191 includes a programmable central processing unit (CPU) 192 that is operable with a memory 194 and a mass storage device, an input control unit, and a display unit (not shown), such as power supplies, clocks, cache, input/output (I/O) circuits, and the liner, coupled to the various components of the processing system to facilitate control of the substrate processing.

To facilitate control of the processing chamber 100 described above, the CPU 192 may be one of any form of general purpose computer processor that can be used in an industrial setting, such as a programmable logic controller (PLC), for controlling various chambers and sub-processors. The memory 194 is coupled to the CPU 192 and the memory 194 is non-transitory and may be one or more of random access memory (RAM), read only memory (ROM), floppy disk drive, hard disk, or any other form of digital storage, local or remote. Support circuits 196 are coupled to the CPU 192 for supporting the processor. Applications or programs for charged species generation, heating, and other processes are generally stored in the memory 194, typically as software routine. The software routine may also be stored and/or executed by a second CPU (not shown) that is remotely located from the processing chamber 100 being controlled by the CPU 192.

The memory 194 is in the form of computer-readable storage media that contains instructions, that when executed by the CPU 192, facilitates the operation of the processing chamber 100. The instructions in the memory 194 are in the form of a program product such as a program that implements the method of the present disclosure. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are aspects of the present disclosure.

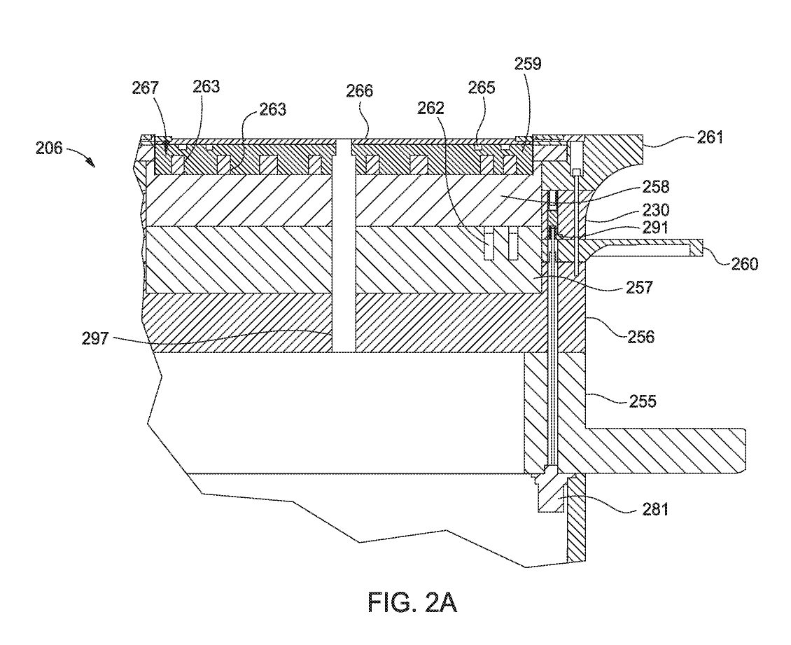

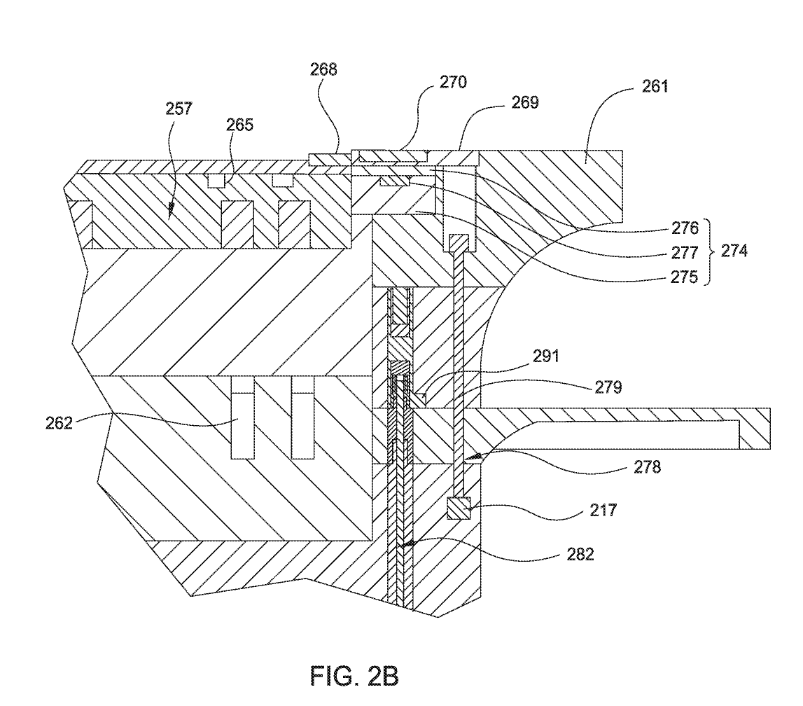

FIGS. 2A-2B are schematic sectional views of a support assembly 206, according to one aspect of the disclosure. FIG. 2B is an enlarged view of FIG. 2A. The support assembly 206 is similar to, and may be used in place of, the support assembly 106. The support assembly 206 includes a base 255, a cathode base 256, a facilities plate 257, a dielectric plate 258, and an electrostatic chuck 259 arranged in a vertical stack. A vertical opening 297 is arranged thought the cathode base 256, the facilities plate 257, and the dielectric plate 258 to accommodate couplings to power and/or bias sources. The base 255 includes a laterally extending portion which may function as a lower chamber liner. A quartz pipe ring (not shown) may circumscribe the dielectric plate 258 to facilitate electrical insulation of the electrostatic chuck 259 from the cathode base 256. A mesh flow equalizer 260 is disposed adjacent a lower surface of a conductive ring 230, which may be formed from a metal such as aluminum and may be grounded, and a radially-outward upper surface of the cathode base 256 to facilitate plasma containment in the processing chamber 100 (shown in FIG. 1). A baffle ring 261, which is formed form a metal such as aluminum and may be electrically grounded, is positioned on an upper surface of the conductive ring 230 and extends radially outward above the mesh flow equalizer 260. In one example, the baffle ring 261 may optionally include a heater, such as a resistive heating element, embedded therein. In one example, the conductive ring 230 and the baffle ring 261 may be a unitary component.

The facilities plate 257 is formed from an electrically conducting material is positioned between the cathode base 256 and the dielectric plate 258. In one example, the dielectric plate 258 is formed form quartz. The facilities plate 257 optionally includes one or more channels 262 (two are shown) through which a fluid is provided to facilitate temperature control of the substrate support 180 (shown in FIG. 1). An electrostatic chuck 259 includes a conductive plate 267 and a ceramic plate 266 disposed on top of conductive plate 267. One or more electrodes 263, formed from a thin section of conductive material, are embedded in a ceramic or dielectric material of the conductive plate 267. A high voltage DC source is coupled to the one or more electrodes 263 to facilitate chucking of a substrate 101, and a bias RF source is coupled to the conductive plate 267 through a matching network to power a cathode.

A heater 265 may disposed on an upper surface of the electrostatic chuck 259 to facilitate temperature control of the substrate 111. The heater 265 may be, for example, a resistive heater including one or more resistive heating elements. A ceramic layer 266, such as silicon carbide or alumina, is disposed above the heater 235 and provides a protective interface between the heater 235 and/or the electrostatic chuck 259, and the substrate 101.

Referring, to FIG. 2B, a dielectric ring 268, which may be formed from, for example, a ceramic or silicon, is positioned on the radially-outward upper surface of the ceramic layer 266 to provide lateral support to a substrate when electrostatically chucked into position. An insulating support 269, which may be formed from quartz, encircles the dielectric ring 268. The insulating support 269 includes a second silicon ring 270 embedded in an upper surface thereof. The silicon ring 270 facilities coupling of a plasma (not shown), which is generated in the interior volume 108 above the substrate support 206, to an edge ring assembly 274. In such an example, the second silicon ring 270 functions as an electrode, and may be capacitively-coupled to the edge ring assembly 274. In one example, the second silicon ring 270 is mono-crystalline silicon. However, it is contemplated that other forms of silicon, such as polysilicon, may be utilized.

The edge ring assembly 274 includes a ceramic base 275, a ceramic cap 276, and an electrode 277 embedded therebetween. Each of the ceramic base 275, the ceramic cap 276, and the electrode 277 has a circular shape. However, other shapes are also contemplated. In one example, the electrode 277 may be embedded or partially embedded in one or both of the ceramic base 275 and the ceramic cap 276 to protect the electrode 277. In such an example, opposing surfaces of the ceramic base 275 and the ceramic cap 276 may contact one another, for example, at respective radially-inward and radially-outward edges thereof. The electrode 277 may be an electrically conductive wire or flattened ring, such as a foil. In one example, the electrode 277 may be formed from aluminum or copper, or other electrically conductive metals or materials. In one example, the electrode 277 may be a flattened ring having a width of about 0.2 inches to about 0.4 inches, such as about 0.3 inches. While the electrode 277 is illustrated as being centrally positioned with respect to the widths of the ceramic base 275 and the ceramic cap 276, it is contemplated that the electrode may be aligned with a radially inward edge of the ceramic base 275 and the ceramic cap 276. In one example, the electrode 277 is positioned about 1 centimeter from the outer diameter of a substrate, such as substrate 101 shown in FIG. 1.

An upper surface of the ceramic cap 276 is positioned in contact with a lower surface of the insulating support 269 during processing. However, the insulating support 269 may be elevated above and separated from the ceramic cap 276 by a lift mechanism 278. The lift mechanism 278 includes one or more support pins 279 (one is shown) driven by an actuator 217. Vertical actuation of the insulating support 269 results in corresponding actuation of the second silicon ring 270, thereby adjusting the spacing the between the second silicon ring 270 and a plasma formed in the interior volume 108 (shown in FIG. 1) of the processing chamber 100. Additionally, vertical actuation of the insulating support 269 results in adjustment of the spacing the between the second silicon ring 270 and the electrode 277, thereby influencing capacitive coupling therebetween. The positon of the second silicon ring 270 affects a plasma sheath adjacent the second silicon ring 270, and thus, adjacent an edge of a substrate. Therefore, by vertically actuating the second silicon ring 270, the plasma sheath adjacent a substrate edge can be adjusted.

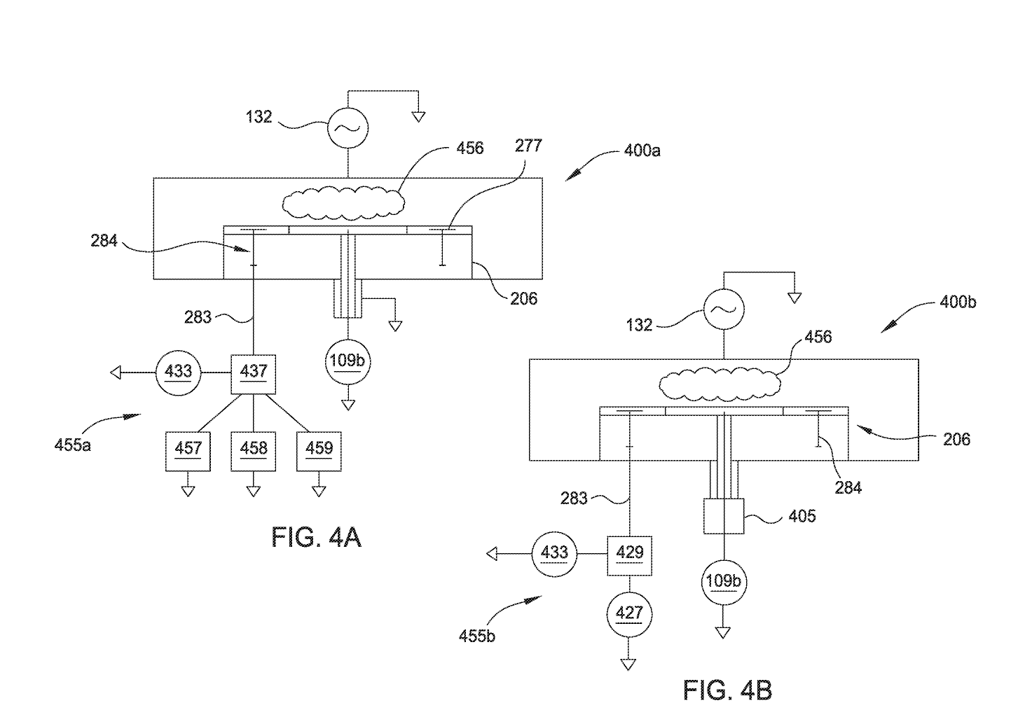

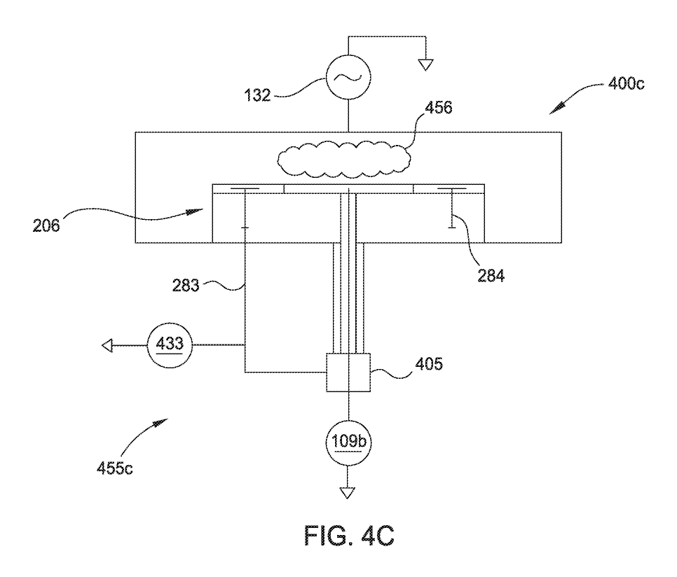

Power is applied to the edge ring assembly 274 through an RF connector 281 and a power distribution assembly 282. The RF connector 281 is coupled to an adjustable RF source (for example, bias source 109b, or shown, for example, in FIGS. 4A-4C) to facilitate transfer of power to the edge ring assembly 274. It is contemplated, however, that in some aspects the edge ring assembly 274 may not be actively powered by RF power. In such an example, an RF connector 281 would be connected to an external RF impedance tuning unit, or tunable load. The tuning unit is designed to adjust impedance at SRC RF frequency to vary plasma density distribution, or to adjust impedance at bias RF frequency to tune substrate edge plasma sheath, or the RF connector 281 may be connected to ground and thus able to locate ground closer to the substrate edge, via a grounded electrode 277 and correspondingly coupled silicon ring 270.

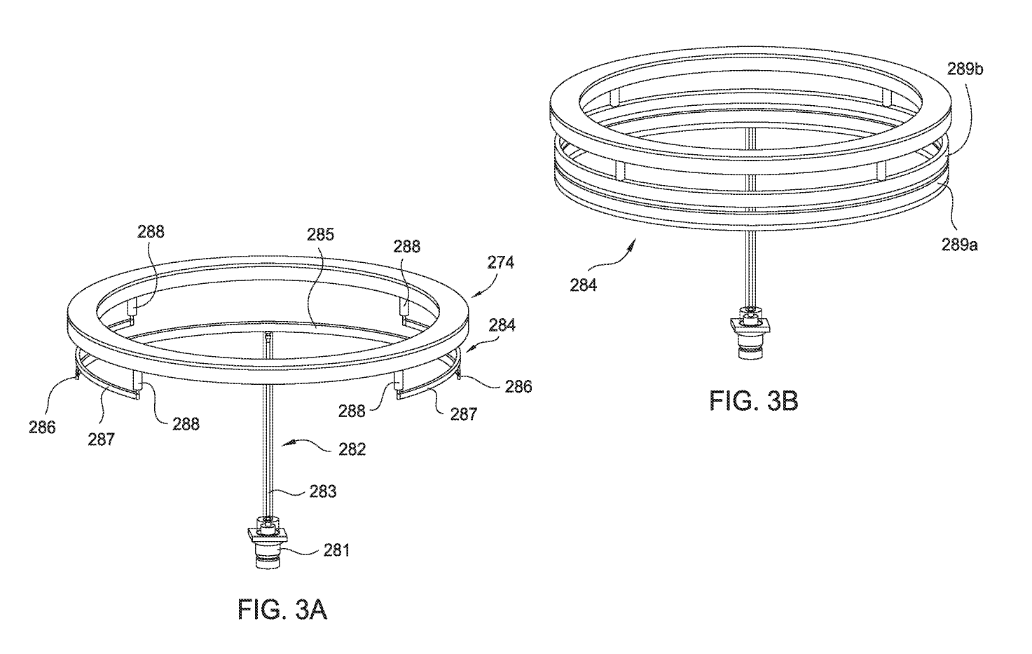

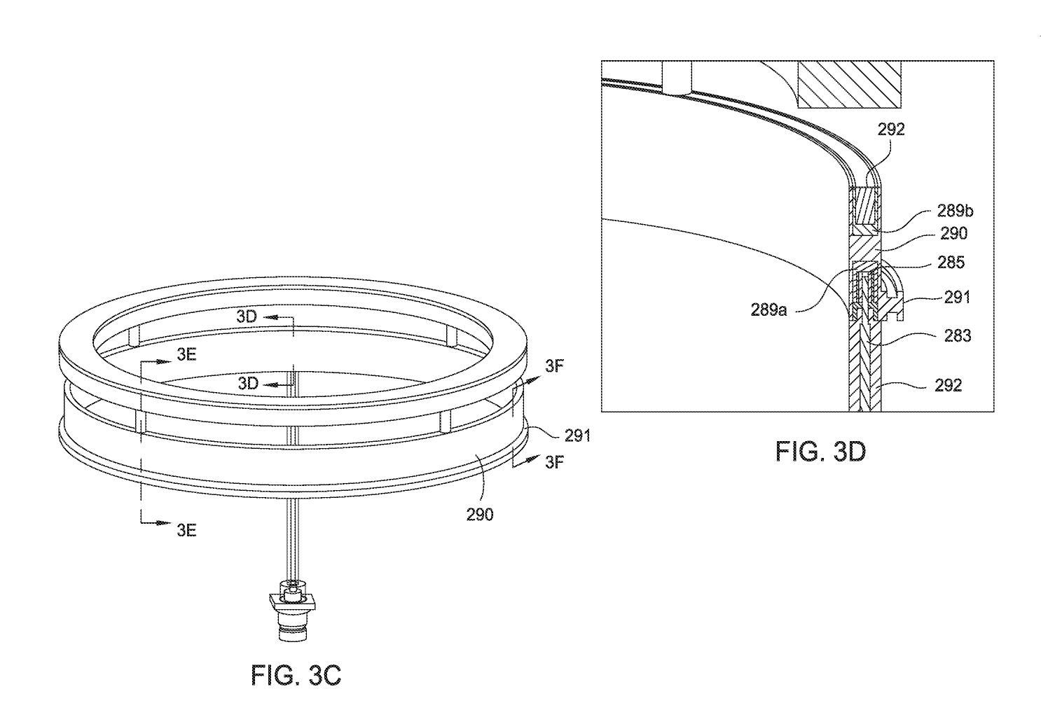

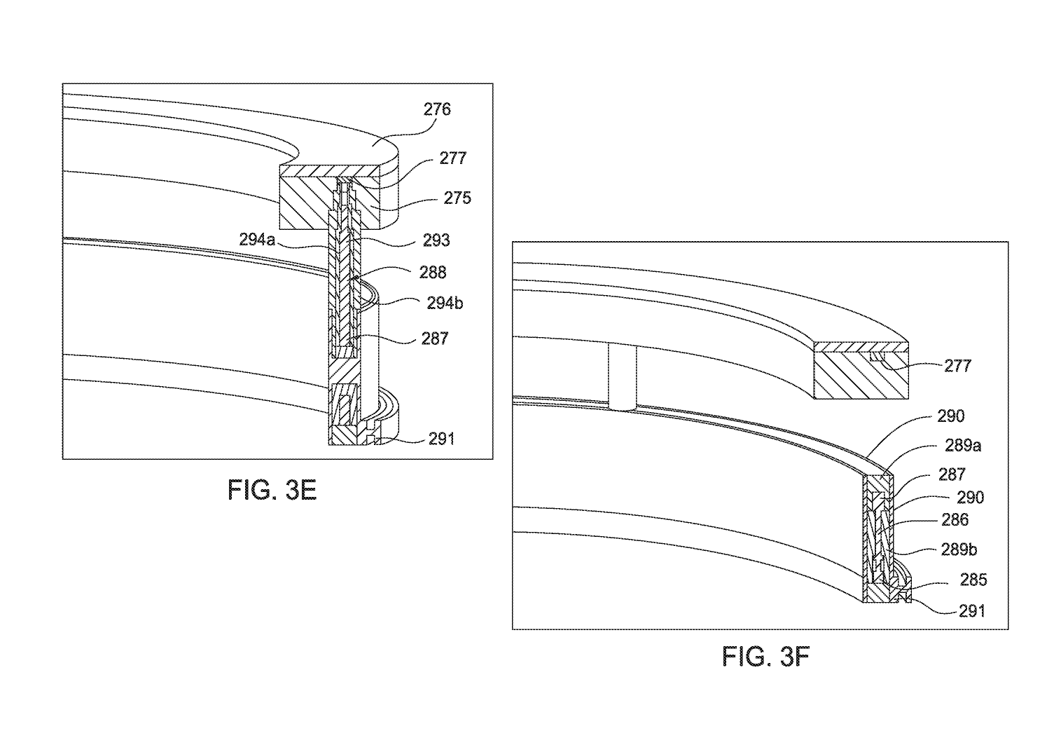

FIGS. 3A-3E are schematic perspective views of a power distribution assembly 282, according to aspects of the disclosure. The power distribution assembly 282 includes a coaxial structure 283 connected to a recursive distribution assembly 284. The edge ring assembly 274 is positioned on and coupled to the recursive distribution assembly 284. The power distribution assembly 282 is electrically connected to the electrode 277 (shown in FIG. 2) of the edge ring assembly 274.

The recursive distribution assembly 284 facilitates power application uniformity to the electrode 277 by diverging into two or more equal length segments. Each diverging segment may further split or diverge into additional equal length segments. Thus, power application to the electrode 277 is more evenly distributed, thereby improving process uniformity. For example, the recursive distribution assembly 284 includes a first semi-circular element 285 electrically coupled to the coaxial structure 283 at a central location of the first semi-circular element 285. Each half the first semi-circular element 285 extends oppositely from another. Terminal ends of the first semi-circular element 285 include vertical couplings 286 extending orthogonally from a plane of the first semi-circular element 285. The vertical couplings 286 electrically connect the first semi-circular element 285 to second semi-circular elements 287. The vertical couplings 286 are connected at central locations of the second semi-circular elements 287 such that each end of the second semi-circular elements 287 extends in opposite directions. Additional vertical couplings 288 electrically couple the second semi-circular elements 287 to the electrode 277 (shown in FIG. 2B) of the edge ring assembly 274. In such a manner, power from a single source, e.g., through the RF connector 281, is more evenly distributed through multiple contact points to the electrode 277. Additionally, the distance between the RF connector 281, and thus a power source, to each connection at the electrode 277 is substantially the same. In one example, the first semi-circular element 285, the second semi-circular elements 287, and the vertical couplings 288 are formed form an electrically conductive material, such as a metal, for example copper or aluminum.

A recursive distribution assembly 284 as used herein refers to an electrical connector which splits one or more times into multiple segments of equal lengths. While recursive distribution assembly 284 is described herein with respect to semi-circular components, it is contemplated linear components may be utilized, where desired. Moreover, the travel path of the electrical current may be split into more sections than shown. For example, the travel path may be split one or more times, two or more times, three or more times, or four or more times. In one example, the first semi-circular element 285 extends about 180 degrees, while each of the second semi-circular elements 287 extend about 90 degrees. Thus, each segment may have a length of about half of a previous segment. However, other distances are also contemplated. Suitable materials for the first semi-circular element 285, the vertical couplings 286, the second semi-circular elements 287 and the vertical couplings 288 include electrically materials, such as metals, for example aluminum and copper.

FIG. 3B is a schematic view of a power distribution assembly 282 having electrical insulators 289a, 289b disposed over electrically conductive elements of the recursive distribution assembly 284, such as the first semi-circular element 285 (shown in FIG. 3A) and the second semi-circular element 287 (shown in FIG. 3A). The electrical insulators 289a, 289b may be polytetrafluoroethylene (PTFE) or another electrically insulating material. In the illustrated example, the electrical insulators 289a, 289b are complete rings of insulating material having components (e.g., the first semi-circular element 285 and the second semi-circular element 287) embedded therein. However, it is contemplated that incomplete rings of material may be utilized.

FIG. 3C is a schematic view of a power distribution assembly 282 including a housing 290 disposed about the electrical insulators 289a, 289b (shown in FIG. 3B). The housing 290 is a cylindrical section having the electrical insulators 289a, 289b, and thus the first semi-circular element 285 and the second semi-circular element 287 embedded therein. The housing may be coupled to an electrical ground, and is electrically isolated from the first semi-circular element 285 and the second semi-circular element 287 electrical insulators 289a, 289b. In one example, the housing 290 includes a lip 291 at a radially outward lower surface thereof, circumscribing the housing 290. In one example, the lip 291 has an “H” shape, or otherwise includes a radially inward component coupled to a radially outward component have a larger vertical height than the radially inward component. The lip 291 facilities assembly and/or alignment of components of the recursive distribution assembly. The housing 290 may be formed from a metal and may be electrically grounded.

FIG. 3D is a sectional view of the power distribution assembly 282 as shown in FIG. 3C. As illustrated, the coaxial structure 283, which is surrounded by an electrical insulator 292 such as rubber or PTFE, is connected to the first semi-circular element 285. The first semi-circular element 285 is surrounded by electrical insulator 289a and disposed in the housing 290. Positioned axially above the first semi-circular element 285 is the electrical insulator 289b. Because the second semi-circular element 287 does not extend in a complete circle, additional electrical insulator 292 may be positioned within the electrical insulator 289b to occupy space which is otherwise unoccupied by the second semi-circular element 287. The additional electrical insulator may also be formed from PTFE. Although not shown, space within the electrical insulator 289b which is unoccupied by the first semi-circular element 285 may also be occupied by PTFE. Thus, in one example, the additional electrical insulator 292 and the second semi-circular element 287 together form a complete ring. The first semi-circular element 285 may be similarly configured.

FIG. 3E is another sectional view of the power distribution assembly 282 as shown in FIG. 3C. The sectional view shown in FIG. 3E illustrates a vertical coupling 288 electrically connecting the second semi-circular element 287 to an electrode 277 of the edge ring assembly 274. The vertical coupling 288 includes an electrically conductive connection 293 surrounded by one or more layers of electrical insulation 294a, 294b (two are shown), such as PTFE. The vertical coupling extends through a lower surface of the ceramic base 275 to contact the electrode 277.

FIG. 3F is another sectional view of the power distribution assembly 282 as shown in FIG. 3C. The sectional view shown in FIG. 3F illustrates a vertical coupling 286 electrically connecting the second semi-circular element 287 to the first semi-circular element 285. The vertical coupling 286, the first semi-circular element 285, and the second semi-circular element 287 are surrounded by housing 290, electrical insulator 289a, and electrical insulator 289b, respectively. Electrical insulator 289a, and electrical insulator 289b facilitate electrical isolation of the vertical coupling 286, the first semi-circular element 285, and the second semi-circular element 287 from the housing 290, which may be grounded during processing.

FIGS. 4A-4C are schematic views of circuit configurations, according to aspects of the present disclosure. FIG. 4A illustrates a passive configuration of a circuit 455a for adjusting plasma 456 in a processing chamber 400a having a substrate support 206 therein. Processing chamber 400a is similar to processing chamber 100. The plasma 456 is generated by the source 132. A bias source 109b is coupled to the substrate support 206 to facilitate plasma processing within the processing chamber 400a. A circuit 455a is coupled to an electrode 277 through the coaxial cable 283 and the recursive distribution assembly 284. Tuning of the circuit 455a affects electrical properties of the electrode 277, thereby influencing the plasma 456, or a sheath of the plasma 456, adjacent a substrate. Using aspects described herein, the plasma 456 may be adjusted to result in more uniform processing of a substrate, thereby mitigating substrate edge non-uniformities.

The circuit 455a includes a ground adjustment 457, a bias-sensitive adjustment 458, and a source-sensitive adjustment 459. Each of the ground adjustment 457, the bias-sensitive adjustment 458, and the source-sensitive adjustment 459 are coupled to the coaxial structure 283 via a switching element 437. Each of the ground adjustment 457, the bias-sensitive adjustment 458, and the source-sensitive adjustment 459 include an adjustable capacitor and an inductor. Each capacitor and inductor of the ground adjustment 457, the bias-sensitive adjustment 458, and the source-sensitive adjustment 459 may be selected to adjust bias frequency, or range of bias frequencies, to facilitate adjustment of plasma characteristics. In one example, the ground adjustment 457, the bias-sensitive adjustment 458, and the source-sensitive adjustment 459, are each configured to facilitate frequency adjustment in different ranges from one another.

Additionally, a power source 435, such as a DC power source, is additionally coupled to the switching element 437. The switching element 437 can be controlled by a controller 191 (shown in FIG. 1) to selectively couple the electrode 277 to any of the power source 433, the ground adjustment 457, the bias-sensitive adjustment 458, and/or the source-sensitive adjustment 459. Thus, modulation of the switching element 437 facilitates control of plasma characteristics at the electrode 277 adjacent a substrate edge.

For example, the switching element 437 may be caused to couple the bias-sensitive adjustment 458 to the electrode 277. The bias-sensitive adjustment 458 may be adjusted to bring the electrode 277 into series or parallel with a fundamental or harmonic frequency of the bias source 109b. Such adjustment imposes a desired voltage on the electrode 277 (and a consequently, the second silicon ring 270 shown in FIG. 2B), thereby altering the local sheath of the plasma 456.

Similarly, the source-sensitive adjustment 459 may be selected relative to the switching element 437. In such an example, the electrode 277 may be tuned with respect to the power source 132, in a manner similarly described above with respect to the bias-sensitive adjustment 458 and the bias source 109b. Tuning of the plasma 456 via the source-sensitive adjustment 459 results in increased (or decreased) plasma density. Increased plasma density results in a compressed plasma sheath.

In another example, the switching element 437 may be caused to couple the ground adjustment 457 to the electrode 277. In one example, the ground adjustment may be an RF relay and/or PIN diode that facilitates grounding of the electrode 277. Grounding of the electrode 277 facilitates termination of a sheath of the plasma 456 at the electrode 277. To further influence the plasma 456, the second silicon ring 270 (shown in FIG. 2b) may be vertically actuated when the electrode 277 is grounded, thereby providing increased plasma tunability adjacent a substrate edge. In one example, when utilizing a PIN diode, the PIN diode may be forward biased to form a DC short at the electrode 277, or may be reverse biased to facilitate electrical disconnection. In another example, the power source 433 facilitates electrostatic chucking of the second silicon ring 270 toward the electrode 277, thus increasing thermal contact between the second silicon ring 270, the insulating support 269 (shown in FIG. 2B), and the edge ring assembly 274. The increased thermal contact results in increased heat removal, thereby improving component longevity and reducing thermal non-uniformities adjacent edges of a substrate.

FIG. 4B illustrates an active configuration of a circuit 455b for adjusting plasma 456 in a processing chamber 400b. Processing chamber 400b is similar to processing chamber 100 and processing chamber 400a. In the active a configuration, the circuit 455b includes an auxiliary power source 427, such as an RF source, coupled to the coaxial cable 283 through a matching circuit 429. The circuit 455b also includes a power source 433 coupled to the matching circuit 429. The power source 433 operates similarly as described above with respect to the processing chamber 400a. In addition, the processing chamber 400b includes a second matching circuit 405 through which the bias source 109b is coupled to the substrate support 206. The substrate support 480 is similar to the substrate support 280 described above with respect to FIG. 2A. The inclusion of the matching circuit 429 and the power source 427 provide additional control over plasma characteristics.

FIG. 4C illustrates an active configuration of a circuit 455c for adjusting plasma 456 in a processing chamber 400c having a substrate support 206 therein. The circuit 455c is similar to the circuit 455b, however, the coaxial cable 283, and thus the recursive distribution assembly 284, are connected to the matching circuit 405. Thus, in contrast to the processing chamber 400b, the matching circuit 429 and the power source 427 are excluded. In one example, an RF divider (not shown) may be positioned in line of the coaxial cable 283 between the matching circuit 405 and the power source 433, or inside the matching circuit 405, to facilitate application of RF power to desired chamber components.

Optionally, it is contemplated that any of the configurations illustrated in FIGS. 4A-4C may optionally utilize a DC power supply coupled to the electrode 277. Application of DC power to the electrode 277 enhances thermal transfer near the edge of a substrate. In such an example, the ceramic cap 276 may be formed from aluminum nitride.

Benefits of the present disclosure include increased control of plasma adjacent edges of a substrate. The increased plasma control results in increased processing uniformity, particularly near edges of the substrate. Additionally, plasma adjustment according to aspects of the present disclosure occurs locally at the substrate edge, thus not adversely affecting plasma uniformity across the substrate surface.

While the foregoing is directed to aspects of the present disclosure, other and further aspects of the disclosure may be devised without departing from the basic scope thereof, and the scope thereof is determined by the claims that follow.

1. A processing chamber, comprising:
a chamber body;
a substrate support disposed within the chamber body;
a recursive distribution assembly disposed within the substrate support;
an edge ring assembly disposed within the substrate support and coupled to the recursive distribution assembly, the edge ring assembly including an electrically conductive electrode;
an insulating support positioned on the substrate support above the electrode; and
a first silicon ring disposed on the insulating support.

2. The processing chamber of claim 1, wherein the substrate support comprises an electrostatic chuck having one or more chucking electrodes.

3. The processing chamber of claim 1, wherein the edge ring assembly comprises a ceramic cap and a ceramic base.

4. The processing chamber of claim 3, wherein the electrode of the edge ring assembly is disposed between the ceramic cap and the ceramic base.

5. The processing chamber of claim 1, further comprising a baffle ring extending radially outward of the edge ring assembly, the conductive ring, and the insulating support.

6. The processing chamber of claim 1, wherein the recursive distribution assembly includes a plurality of diverging electrical connections.

7. The processing chamber of claim 6, wherein the diverging electrical connections have equal lengths.

8. The processing chamber of claim 1, further comprising a lift mechanism disposed within the substrate support, the lift mechanism configured to vertically actuate the silicon ring and the insulating support.

9. The processing chamber of claim 1, wherein the recursive distribution assembly includes a plurality of semi-circular elements.

10. The processing chamber of claim 9, wherein the plurality of semi-circular elements are axially spaced and connected by vertical connections.

11. The processing chamber of claim 9, further comprising polytetrafluoroethylene disposed around the plurality of semi-circular elements.

12. The processing chamber of claim 1, further comprising a circuit coupled to the electrode, the circuit comprising a ground adjustment, a bias-sensitive adjustment, and a source-sensitive adjustment.

13. The processing chamber of claim 12, wherein the circuit comprises a switching element coupling the electrode to the ground adjustment, the bias-sensitive adjustment, and the source-sensitive adjustment.

14. A processing chamber, comprising:
a chamber body;
a substrate support disposed within the chamber body;
a recursive distribution assembly disposed within the substrate support;
an edge ring assembly disposed within the substrate support and coupled to the recursive distribution assembly, the edge ring assembly including an electrically conductive circular electrode;
an insulating support positioned on the substrate support above the electrode; and
a first silicon ring disposed on the insulating support.

15. The processing chamber of claim 14, wherein the edge ring assembly comprises a ceramic cap and a ceramic base, and wherein the ceramic base and the ceramic cap are circular.

16. The processing chamber of claim 15, wherein the electrode is disposed between the ceramic base and the ceramic cap.

17. The processing chamber of claim 16, wherein the recursive distribution assembly includes a plurality of diverging electrical connections.

18. The processing chamber of claim 16, wherein the recursive distribution assembly includes a plurality of semi-circular elements.

19. A recursive distribution connector, comprising:
a first semi-circular element;
a coaxial structure coupled to the first semi-circular element at a central portion thereof;
a first vertical coupling disposed at a first end of the first semi-circular element and extending orthogonally from a plane of the first semi-circular element;
a second vertical coupling disposed at a second end of the first semi-circular element and extending orthogonally from the plane of the first semi-circular element;
a second semi-circular element connected to the first vertical coupling, the first vertical coupling connected to a central portion of the second semi-circular element; and
a third semi-circular element connected to the second vertical coupling, the second vertical coupling connected to a central portion of the third semi-circular element.

20. The recursive distribution assembly of claim 19, wherein the recursive distribution assembly comprises an electrically conductive material.
